(19) United States
(12) Patent Application Publication
(10) Pub. No.: US 2007/0138915 A1
(43) Pub. Date: Jun. 21, 2007

(54) Piezoelectric micro-device for blockage removal

(76) Inventors: Maureen Mulvihill, Bellefonte, PA (US); Kenji Uchino, State College, PA (US); Gareth Knowles, Williamsport, PA (US); Robert Harbaugh, Hershey, PA (US)

Correspondence Address: Michael G. Crilly, Esquire, 104 South York Road, Hatboro, PA, 19040, US

(21) Appl. No.: 11/636,929

(22) Filed: Dec. 11, 2006

Related U.S. Application Data
(60) Provisional application No. 60/751,066, filed on Dec. 16, 2005.

(51) Int. Cl. H01L 41/08

(52) U.S. Cl. 310/328

(57) ABSTRACT

A piezoelectric micro-disruptor capable of disrupting a blockage both mechanically and vibrationally is presented. The micro-disruptor includes a rotor, a stator disposed about and contacting the rotor, a cutting element, and a flexible guide wire. In one embodiment, the stator is composed of a flexible cylinder with at least two piezoelectric elements attached thereto. Piezoelectric elements are electroded, wired to power leads within the flexible guide wire, and poled to function as an actuator. Expansion and contraction of the piezoelectric elements causes the flexible cylinder to wobble, thus driving the rotor and cutting element in a rotary fashion. In another embodiment, the stator is a piezoelectric cylinder with at least two electrodes attached separately thereto so as to contact and rotate a rotor assembly. Piezoelectric elements and cylinder are electrically driven so as to vibrate the stator, rotor, and cutting element. The present invention has immediate applicability within medical devices for the removal and disruption of an embolus, thrombus, kidney stone, gallstone, fatty deposit, or the like.

### CROSS REFERENCE TO RELATED APPLICATIONS

This application is based upon and claims priority under 35 U.S.C. § 119(e) from U.S. Provisional Application No. 60/751,066 filed Dec. 16, 2005, entitled Ultrasonic Micro-Device for the Removal of Intra-Vascular Blockages, the contents of which are hereby incorporated in its entirety by reference thereto.

### FEDERALLY SPONSORED RESEARCH AND DEVELOPMENT

None.

### BACKGROUND OF THE INVENTION

1. Field of the Invention

The present invention generally relates to a device for disrupting a blockage within an artery, vein, canal, duct, tube, or the like via mechanical and vibrational means. Specifically, the invention is a remotely operable micro-motor having a rotor mechanically coupled to a cutting element so that both rotor and cutting element are driven in a rotating fashion and simultaneously vibrated by at least one piezoelectric element disposed about the rotor.

2. Description of the Related Art

Generally, a blockage is an agglomeration of organic or inorganic material within a conduit which partially or completely impedes the flow of a fluid. A variety of blockages are possible within a living organism. A vascular blockage is one specific example whereby a fibrous mass or plaque adheres to the wall of a vascular structure so as to impede blood flow therein.

Approximately seven hundred and fifty thousand individuals experience one or more blockage-related strokes within the United States on an annual basis. Seventy to eighty percent of all stroke victims suffer an ischemic stroke characterized by an embolism blocking a cerebral artery so as to impede the flow of oxygen and nutrients to the brain. A majority of ischemic strokes cause irreparable damage to and lose of brain cells within minutes of a blockage. As such, an embolism must be removed as quickly as possible to minimize cellular damage and to ensure full recovery. Cerebral blockages are among the most difficult to effectively treat because of the size and remoteness of vasculature within the brain.

A variety of drugs and medical devices are presently available to clear intravascular blockages, including those within the brain. A small embolus is typically treated with thrombolytic drugs; however, thrombolytic drugs are not effective in the treatment of a large embolus. As such, intravascular devices are required to break up and/or remove larger blockages.

Intravascular devices fall into one of four distinctly separate devices, namely, instruments which ensnare a blockage for removal, instruments which drill through a blockage to re-canal an artery or the like, instruments which pulverize a blockage via ultrasonic means, and instruments which employ a stent or balloon to expand an opening through a blockage. Presently known devices are not completely effective, difficult to use, and too bulky to reach many cerebral arteries. Thus, a medical micro-device capable of clearing a blockage is sorely needed to enable the safe and efficient intravascular treatment of embolus-related and thrombosis-related conditions, particularly those within the brain.

Therefore, what is required is a mechanically simple micro-device capable of disrupting an embolus, thrombosis, or the like within the interior of a vascular structure.

### SUMMARY OF INVENTION

An object of the present invention is to provide a mechanically simple micro-device capable of disrupting an embolus, thrombosis, or the like within the interior of a vascular structure.

The present invention is a micro-disruptor composed of a piezoelectric micro-motor attached to a catheter and having a cutting element disposed at one end so as to rotate because of frictional contact with a stator moving in an elliptical path. The micro-disruptor includes a remotely operable micro-motor having a rotor mechanically coupled to a cutting element so that both rotor and cutting element are driven in a rotating fashion by one or more piezoelectric elements disposed about the rotor. The invention mechanically clears a blockage within a vascular cavity by either reestablishing a canal through the blockage or by ensnaring and removing the blockage. Furthermore, the invention fragments a blockage via vibrational energy originating within the micro-motor and communicated to the cutting element. The particulated blockage may be dissolved by thrombolytic drugs, one example being a tissue plasminogen activator (t-PA).

Several advantages are noteworthy.

The present invention fragments a blockage into particulates which are smaller than those produced by other devices. Smaller particulates are more efficiently dissolved by a thrombolytic drug, thus reducing both level and exposure time required to clear a blockage and minimizing the risk of a cerebral hemorrhage.

The present invention includes a piezoelectric micro-motor having a higher power-to-volume ratio and a higher power-to-weight ratio than motor driven devices presently known within the art.

The present invention produces high torque and low speed drive without gear mechanisms, is more efficient than electromagnetic motors, and produces no electromagnetic interference.

The present invention may be used with Magnetic Resonance Imaging (MRI) equipment to visually guide the micro-disrupter.

The present invention is sufficiently small so as to maneuverability through cerebral vasculature.

### REFERENCE NUMERALS

1 Micro-disruptor
2 Micro-motor
3 Cutting element
4 Guide wire
5 Rotor
6 Stator
7 Spring
8 Ferrule
9 Ferrule
10 Piezoelectric element
20 Vascular structure
21 Blockage
22 Blood
23 Particulate
24 Piezoelectric cylinder
25 Electrode
26 Cutting element
27 Tube shaped sheath
28 Electrode
29 Piezoelectric element
11 Piezoelectric element
12 Flexible cylinder
13 Support cylinder
15 Ferrule
16 Micro-motor
17 Rotor
18 Ferrule
19 Ferrule
30 Piezoelectric element
31 Tapered surface
32 Tapered surface
34 Driver circuit
35 Stator
36 Piezoelectric element
37 Power supply
38 Flexible cylinder

### BRIEF DESCRIPTION OF THE DRAWINGS

The invention will now be described in more detail, by way of example only, with reference to the accompanying drawings, in which:

FIG. 1 is a section view of an artery showing the present invention penetrating a blockage within a vascular structure.

FIG. 2 is a section view of one embodiment of the micro-disruptor including a micro-motor having a stator and a support cylinder disposed about a rotor, a cutting element attached to the rotor at one end of the micro-motor, and a flexible guide wire attached to the micro-motor so that a portion of the rotor and cutting element extend therefrom.

FIG. 3a is a perspective view of a two-phase stator having a pair of piezoelectric elements arranged in a perpendicular fashion about and attached to a flexible cylinder wherein each piezoelectric element has an electrode attached thereto opposite of the flexible cylinder.

FIG. 3b is a top plan view of the two-phase stator shown in FIG. 3a.

FIG. 3c is a top plan view of a four-phase stator having four piezoelectric elements arranged in a perpendicular fashion and disposed about a flexible cylinder wherein each piezoelectric element has an electrode attached thereto opposite of the flexible cylinder.

FIG. 4a is a section view of an alternate embodiment of the micro-disruptor wherein the stator is a piezoelectric cylinder having at least two electrodes substantially and separately embedded within the piezoelectric cylinder which is disposed about and contacts a rotor with cutting element at one end.

FIG. 4b is a section view of a multi-phase embodiment of the stator shown in FIG. 4a.

FIG. 5 is a schematic representation of the two-phase stator in FIGS. 3a-3b at various flexure states induced by a pair of piezoelectric elements perpendicularly disposed about a flexible cylinder so as to rotate a rotor extending through the stator in a generally elliptical path.

FIG. 6 is a schematic diagram showing functional control of four electroded piezoelectric elements disposed about and attached to a flexible cylinder wherein a driver circuit controls both ON and OFF functionality of each piezoelectric element (via sine, cosine, -sine, and -cosine waveforms) so as to deform the flexible cylinder and rotate the rotor in either a clockwise or counter-clockwise direction.

### DETAILED DESCRIPTION OF THE INVENTION

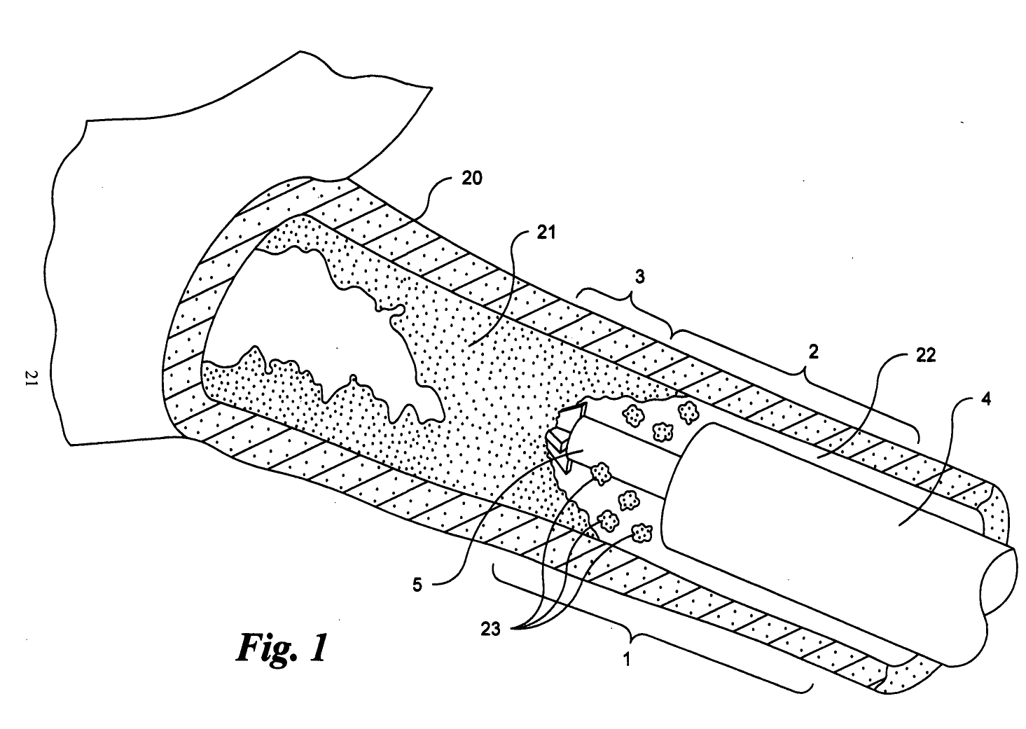

Referring now to FIG. 1, the present invention, referred to hereafter as the micro-disruptor 1, is shown within a vascular structure 20, examples including arteries and veins. A cutting element 3 attached to a rotor 5 is shown extending from one end of the micro-motor 2 and penetrating a blockage 21, examples including an embolus and thrombosis. In this example, the micro-disruptor 1 disrupts the blockage 21 into fragments or particulates 23 which thereafter are suspended within blood 22 passing through the vascular structure 20. Particulates 23 may be dissolved with drugs known within the art.

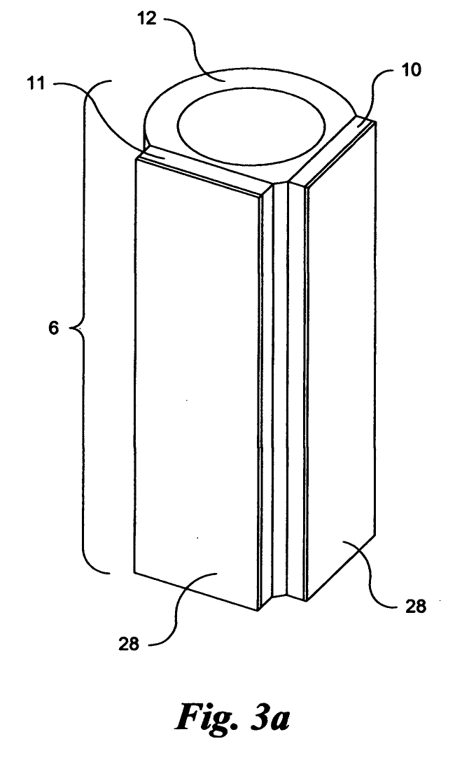

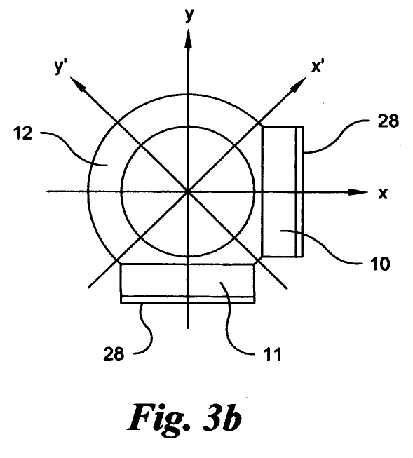

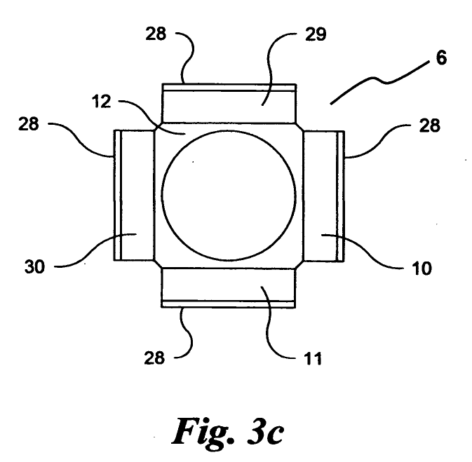

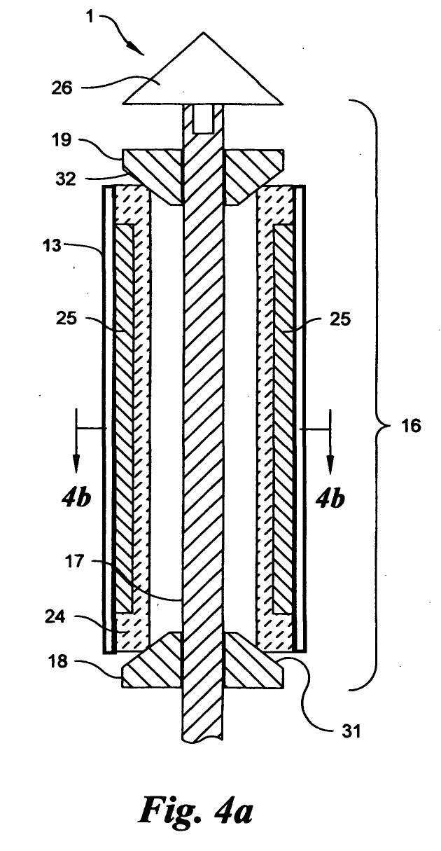

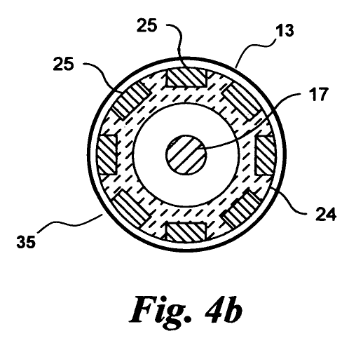

The micro-disruptor 1 is attached to a flexible guide wire 4, typically a catheter-like device understood in the art, so as to enable the controlled insertion, removal, placement, and operation of the micro-disruptor 1 within an artery, vein, tube, duct, or canal. Furthermore, the guide wire 4 communicates power to either piezoelectric elements 10, 11, 29, 30 shown in FIGS. 3a-3c or piezoelectric cylinder 24 shown in FIGS. 4a-4b so as to control operation of the micro-motor 2 or 16, respectively.

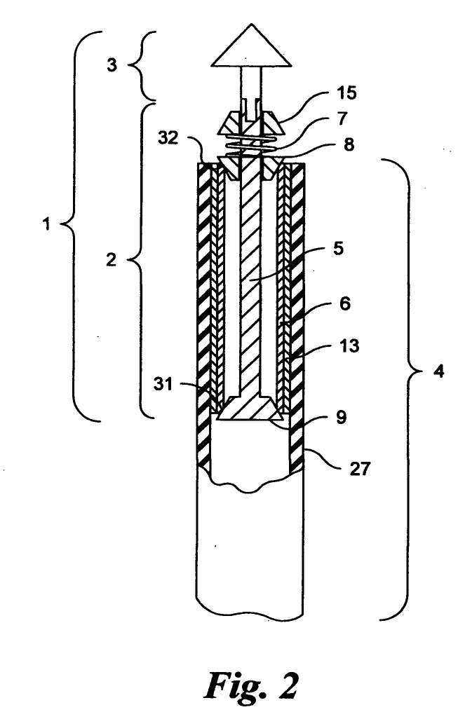

Referring now to FIG. 2, the micro-disruptor 1 is comprised of a micro-motor 2 having a rotatable rod-shaped rotor 5 therein and disposed along the central axis of the micro-motor 2. At one end of the rotor 5 is a disk-shaped ferrule 9 with tapered surface 31 and adjacent to the other end of the rotor 5 is a second disk-shaped ferrule 8 with tapered surface 32. It is preferred that ferrules 8, 9 be composed of a polymer, composite, or metal. Both tapered surfaces 31, 32 are inwardly disposed and complimentary, as shown in FIG. 2.

In some embodiments, the ferrule 8 is disposed about and fixed to the rotor 5. During assembly, the stator 6 is placed over the rotor 5 and the ferrule 8 is placed onto the rotor 5 in a sliding fashion and mechanically or adhesively attached to the rotor 5.

Ferrule 9 and rotor 5 may be a single-piece element composed of a polymer, composite, or metal. In yet other embodiments, the ferrule 9 may be a disk-shaped element which is placed onto the rotor 5 in a sliding fashion and mechanically or adhesively locked onto the rotor 5. Mechanical attachment of ferrules 8, 9 to the rotor 5 may be via threads, set screw, fastener, or the like. Adhesive attachment may be via an epoxy or the like.

In some embodiments, a second disk-shaped ferrule 15 composed of a polymer, composite, or metal is disposed about and attached to the rotor 5 in a fixed fashion either mechanically or adhesively as described above. An optional spring 7, also composed of a polymer or metal, is likewise disposed about the rotor 5 and between ferrules 8 and 15 so as to maintain positive contact between the lower most ferrule 8 and stator 6. Application of the optional spring 7 does not require the ferrule 8 to be fixed to the rotor 5, but rather it is preferred for the ferrule 8 to slide along the rotor 5 between the stator 6 and second ferrule 15.

A stator 6 is disposed about the rotor 5 as represented in FIG. 2. The stator 6 typically has an inner diameter and length so that the ends thereof contact the respective tapered surfaces 31, 32. Frictional contact between stator 6 and tapered surfaces 31, 32 prevent rotation of the rotor 5 when the micro-motor 2 is OFF.

The stator 6 may be housed within a support cylinder 13 composed of a polymer, non-conductive metal, or metal with non-conductive coating. The support cylinder 13 contacts the stator 6 and constrains flexure of the stator 6 onto the ferrules 8, 9 so as to effect rotation of the rotor 5.

A cutting element 3 is provided at the end of the rotor 5 opposite of the outermost ferrule 8 or 15 and aligned with the central axis of the rotor 5. For purpose of the present invention, the cutting element 3 may include a micro-size drill bit or the like to establish a cavity through a blockage, a single or multi-blade device to cut through a blockage, or a screw-shaped snare device to ensnare a blockage. FIG. 1 shows an exemplary blade-type device with cutting blades.

It is preferred for the cutting element 3 to be mechanically joined to a cavity within the rotor 5 and fastened thereto via threads, set pin, or screw so as to prevent separation between cutting element 3 and rotor 5 during use. It is also possible for the cutting element 3 and rotor 5 to be composed of a single-piece construction. Dimensions of cutting element 3 and micro-motor 2 are application dependent.

The micro-motor 2 is preferred to be housed within the guide wire 4 so that a portion of the rotor 5 and cutting element 3 extend beyond the end of the guide wire 4, as represented in FIG. 2. The micro-motor 2 is surrounded by and adhesively attached to the flexible, tube-shaped sheath 27 along the guide wire 4.

Referring now to FIG. 3a, one embodiment of the stator 6 is shown comprising a flexible cylinder 12 having a pair of electrically activated piezoelectric elements 10, 11 attached thereto in a perpendicular arrangement. For purpose of the present embodiment, the micro-motor 2 is an N-phase device, where N represents the number of piezoelectric devices contacting the flexible cylinder 12. In preferred embodiments, N is an even number allowing for the paired arrangement of piezoelectric elements 10, 11. As such, the stator 6 in FIG. 3a provides a two-phase (e.g., sine and cosine) stator 6 and micro-motor 2.

The flexible cylinder 12 is composed of material capable of repeated and sustained flexure. For example, the flexible cylinder 12 may be fabricated of a polymer, composite, or ductile metal, preferably non-conductive or having a non-conductive coating thereon.

Piezoelectric elements 10, 11 are composed of a piezoelectric polycrystalline or single crystal, preferably lead zirconate titanate or lead magnesium niobate-lead titanate respectively. Piezoelectric elements 10, 11 are generally planar shaped and electroded, wired, and poled via techniques understood in the art to function as actuators. However, it is likewise possible for the piezoelectric elements 10, 11 to have a curvature which approximates the outer surface of the flexible cylinder 12.

When piezoelectric elements 10, 11 are planar in extent, the outer circumference of the flexible cylinder 12 is preferred to have planar sides, as shown in FIG. 3b, so as to ensure direct and continuous contact between the flexible cylinder 12 and each piezoelectric element 10, 11. Piezoelectric elements 10, 11 may be adhesively bonded to the flexible cylinder 12 or mechanically fastened or embedded therein. It is likewise possible for three or more planar piezoelectric elements 10, 11, 29, 30 and electrodes 28 to be attached to the flexible cylinder 12, as represented by the four-phase stator 6 in FIG. 3c. In yet other embodiments, piezoelectric elements 10, 11 may be curved or cylindrically shaped and attached to the flexible cylinder 12.

Referring now to FIG. 4a, an alternate embodiment of the micro-motor 16 is shown comprising a piezoelectric cylinder 24 disposed about a rotor 17. A pair of disk-shaped ferrules 18, 19, each having a tapered surface 31, 32 thereon, respectively, is either mechanically or adhesively attached to the rotor 17. Ends of the piezoelectric cylinder 24 directly contact the tapered surfaces 31, 32, as represented in FIG. 4a. A cutting element 26 is attached to the rotor 17, as previously described.

For purpose of the present embodiment, the micro-motor 16 is an N-phase device, where N represents the number of electrodes 25 contacting the piezoelectric cylinder 24. As such, the stator 35 in FIG. 4b shows an eight-phase device and micro-motor 16.

In the present embodiment, the stator 35 consists of both piezoelectric cylinder 24 and electrodes 25. The piezoelectric cylinder 24 has a length and inner diameter which ensures contact between the ends thereof and tapered surfaces 31, 32. Electrodes 25 are preferred to be foils or flexible plates which are rectangular shaped and disposed lengthwise along the length of the piezoelectric cylinder 24, as represented in FIGS. 4a-4b.

The stator 35 may be housed within a support cylinder 13, composed of a polymer, non-conductive metal, or metal with non-conductive coating. The support cylinder 13 contacts the stator 35 and constrains flexure of the stator 35 onto the ferrules 18, 19 so as to effect rotation of the rotor 5.

Two or more electrodes 25 are mechanically attached to or otherwise embedded within the piezoelectric cylinder 24. Power is communicated to electrodes 25 so as to extend and contract the piezoelectric cylinder 24 within a localized region. Selective extension and contraction of the piezoelectric cylinder 24 causes the cylinder to distort in a wobble-like fashion producing intermittent contact between the ferrules 18, 19 and the ends of the piezoelectric cylinder 24. Rotor 17 and ferrules 18, 19 are movable within the micro-motor 16 and driven in a generally elliptical path via the controlled excitation of the piezoelectric cylinder 24.

High power piezoelectric applications require high AC drive voltages at resonance to induce large vibrational strains. The performance of soft PZT materials is degraded by heating because of losses resulting from domain reorientation. Hard PZT materials exhibit lower loss and have greater Qₘ values than soft PZT materials, where Qₘ is equal to 1/tan δₘ. Piezoelectric strain at resonance is enhanced by the factor Qₘ. For example, the figure-of-merit for the vibration amplitude of a rectangular plate is equal to the product of Qₘ and d. Therefore, the higher Qₘ values for hard PZT materials yield a higher figure-of-merit and resultantly a larger change in length than soft PZT materials.

Ferroelectric polycrystalline ceramics, such as barium titanate and lead zirconate titanate, exhibit piezoelectricity when electrically poled. Acoustic and ultrasonic vibrations are produced when an alternating field is tuned to the mechanical resonance frequency of the piezoelectric device. In the present invention, vibrations generated within the micro-motor 2, 16 are communicated to the cutting element 3, 26 so as to enhance the pulverization and/or removal of a blockage 21.

In the present invention, piezoelectric elements 10, 11, 29, 30 and piezoelectric cylinder 24 are vibratory devices functioning in a resonant vibrational mode. Rotation is produced by mechanically coupling distortion of the flexible cylinder 12 produced by the vibration of the piezoelectric elements 10, 11, 29, 30 in a coupled arrangement to the rotor 5 or by the piezoelectric cylinder 24 to the rotor 5. Friction along contact points between flexible cylinder 12 and ferrules 8, 9 or piezoelectric cylinder 24 and ferrules 18, 19 produce the desired rotational motion. The large-force, high-frequency functionality of the piezoelectric elements 10, 11, 29, 30 and piezoelectric cylinder 24 allows for large linear or rotary-wave travel that is fast, precise, and small.

Piezoelectric elements 10, 11, 29, 30 and piezoelectric cylinder 24, within the micro-motors 2, 16 described above, are electrically coupled at an AC voltage supply via electrical leads within the guide wire 4. The power required to operate a typical micro-motor 2, 16 may be less than 100 mW (40-50Vᵢₙ) when functioning at a resonant drive frequency from 80 to 100 kilohertz. Micro-motors 2, 16 described herein have a high holding torque even when no power is applied to the piezoelectric elements 10, 11, 29, 30 or piezoelectric cylinder 24.

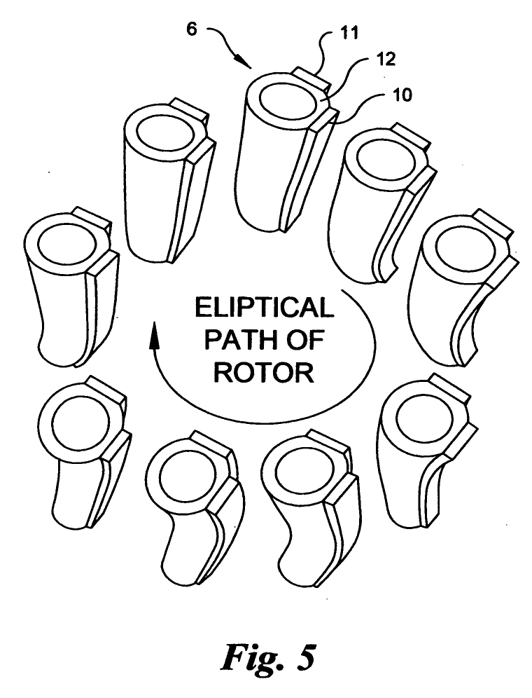

Referring now to FIG. 5, the wobble-like motion along the flexible cylinder 12 of the stator 6 is produced when one piezoelectric element 10, 11 in a paired arrangement is excited at a frequency between two orthogonal bending mode frequencies. When the other piezoelectric element 10 or 11 is excited at the same frequency, the direction of wobble is reversed. The described wobble drives a rotor 5 in a generally elliptical path. In some embodiments, rotation of the rotor 5 is preferred to be continuous so as to drill or cut through a blockage. In other embodiments, rotation of the rotor 5 is preferred to be intermittent or limited so as to ensnare a blockage.

Referring again to FIG. 1, the micro-motor 2 must have sufficient power and torque to rotate the cutting element 3 as it penetrates and disrupts the blockage 21. The cutting element 3 must exert a shear stress that is greater than the maximum shear strength of the clot, which is composition dependent. For example, the strength of a fibrous blockage depends on the strength and density of the fibers comprising the blockage 21. The strength of fibrous blood clots is broadly estimated to be from 3,000 to 10,000 dynes-per-square-centimeter.

Assuming a drill bit type cutting element 3, the torque applied onto the blockage 21 is estimated by
Tₘₒₜₒᵣ=F_{drill}×R_{drill} (1)
and the force applied by the cutting element 3 onto the blockage 21 is estimated by
σ_{drill}=F_{drill}/Aₘₐₜₑᵣᵢₐₗ₋ₛₕₑₐᵣ≧σ_{B} (2)
where Tₘₒₜₒᵣ (N×m) is the torque, F_{drill} is the force applied by the cutting element 3, R_{drill} is the radius of the drill tooth (m), Aₘₐₜₑᵣᵢₐₗ₋ₛₕₑₐᵣ is the area based on the drill tooth (m²), σ_{drill} is the calculated stress, and σ_{B} is the strength of the blockage 21. The drill force is then applied to the contact area which is the length of the tooth multiplied by the depth of the drill cut. This relationship also determines the maximum cut depth that the drill can make per revolution. The micro-motor 2 yields a 5,000-Pa shear stress when cutting a blockage 21 assuming a torque equal to 1-mN*m, a flat two tooth drill bit having 1.5-mm diameter, and a cut depth of 0.1-μm. A cut or penetration speed of approximately 0.364 mm-per-minute is achieved assuming a motor speed of 1,800 rotations-per-minute.

The guide wire 4 or catheter attached to the micro-disruptor 1 must withstand torsional loading exerted on it by the drilling process and tangential loading resulting from forcing the micro-disruptor 1 into the blockage 21. Since the guide wire 4 is subjected to two load types simultaneously, the Von Mises failure criterion is appropriate and the following equations are applicable:
τ=Tr/J (3)
σ=P/A (4)
σ_{VM}=(σ²+3τ²)^{1/2} (5)
where τ is the torsional stress (MPa), r is the radius of the guide wire 4 (m), J is the polar moment of inertia for the guide wire 4 (m⁴), σ is the normal stress, P is the applied load, A is the area, and σ_{VM} is the Von Mises stress.

Assuming a guide wire 4 having a 0.2-mm thick wall, the maximum torsional load is never greater than the shear load exerted by the micro-disruptor 1 onto the guide wire 4. In actual practice, the torsional load is equal to the torque required to cut through the blockage 21 and the tangential load is extremely small. Since the area of the guide wire 4 is also extremely small, torsion and tangential stresses within the guide wire 4 are large. In some applications, additional support structure, one example being a braided wire mesh, may be provided within the wall along the guide wire 4 to strengthen the structure.

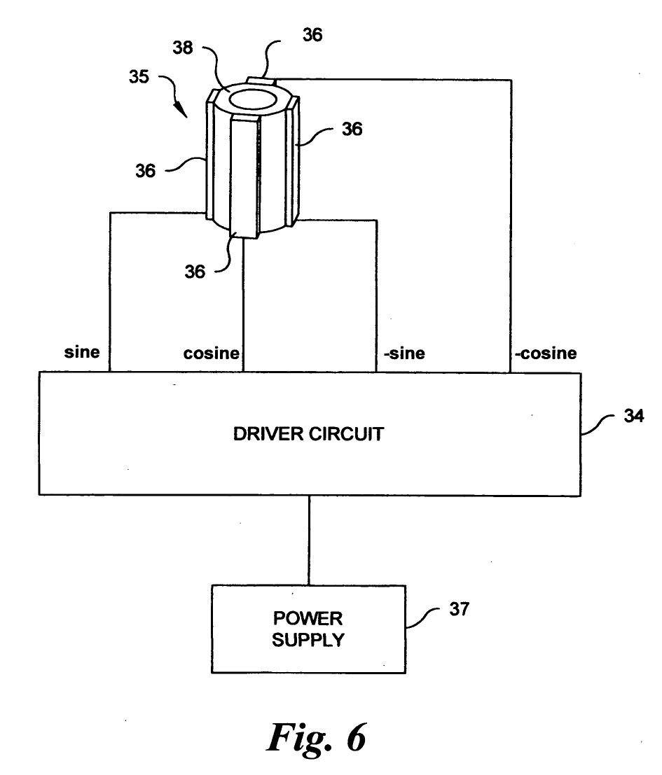

Referring now to FIG. 6, power to piezoelectric elements 36 disposed about a flexible cylinder 38 is provided via a driver circuit 34. One exemplary driver circuit 34 is the μ-drive™ circuitry for driving active capacitive loads as described in U.S. Pat. No. 6,465,931, entitled Device and Method for Driving Symmetric Load Systems. The driver circuit 34 is electrically connected to the piezoelectric elements 36 and an AC power supply 37. Driver circuit 34 selectively communicates power from the power supply 37 to one or more piezoelectric elements 36 so as to achieve either clockwise or counterclockwise rotation within the micro-motor 2.

The micro-disruptor 1 functions on the following principals. The resonance frequencies for square beams have two equivalent orthogonal bending modes. The first bending mode frequency for a circular cylinder is equivalent in any direction. Both modes are incorporated into the stators 6, 35 described above.

Referring again to FIG. 3b, the outer surface of a hollow metal cylinder is flattened on two sides at 90-degrees with respect to each other and a uniformly electroded rectangular piezoelectric element is bonded to each flattened surface. Since the stator 6 is symmetric with respect to the x′-axis, the area moment of inertia about the principal axis is along the x′-axis. The area moment of inertia about the other principal axis is along the y′-axis. The resultant inertias cause the stator 6 to have two degenerated orthogonal bending modes with closely related resonance frequencies.

A split of the bending mode frequencies is caused by asymmetries due to the flat surfaces along the outer surface of the flexible cylinder 12. Driving one piezoelectric element 10, 29 at a frequency between the two orthogonal bending mode frequencies, while short circuiting the other to ground, excites both modes causing the flexible cylinder 12 to wobble. When the other piezoelectric element 11, 30 is driven at the same frequency, the direction of wobble is reversed.

The description above indicates that a great degree of flexibility is offered in terms of the invention. Although the present invention has been described in considerable detail with reference to certain preferred versions thereof, other versions are possible. Therefore, the spirit and scope of the appended claims should not be limited to the description of the preferred versions contained herein.

What is claimed is:

1. A micro-disruptor for disrupting a blockage comprising:
(a) a micro-motor including:
(i) a rotor having a pair of tapered ferrules separately disposed thereon; and
(ii) a stator disposed about said rotor between and contacting said tapered ferrules, said stator including a flexible cylinder with at least two piezoelectric elements outwardly attached thereto, each said piezoelectric element electroded, wired, and poled to function as an actuator, said piezoelectric elements electrically coupled to a driver circuit tuned to the mechanical resonance frequency of said piezoelectric elements so as to vibrate said stator; and
(b) a cutting element extending from one end of said rotor, said rotor communicates vibrations from said stator to said cutting element.

2. The micro-disruptor of claim 1, further comprising a support cylinder disposed about and contacting said stator.

3. The micro-disruptor of claim 2, wherein said piezoelectric elements are disposed in a paired arrangement about said flexible cylinder.

4. The micro-disruptor of claim 2, wherein said piezoelectric elements are planar and one said piezoelectric element is perpendicular to another said piezoelectric element for each said paired arrangement.

5. The micro-disruptor of claim 2, wherein said cutting element is a drill bit, a screw-shaped snare, or at least one blade.

6. The micro-disruptor of claim 2, further comprising:
(c) a guide wire attached to said micro-motor opposite said cutting element.

7. The micro-disruptor of claim 1, further comprising a third ferrule attached to said rotor between said cutting element and one said ferrule adjacent to said cutting element, said ferrule adjacent to said cutting element movable along said rotor and pressed against said stator by a spring.

8. A micro-disruptor for disrupting a blockage comprising:
(a) a micro-motor including:
(i) a rotor having a pair of tapered ferrules separately disposed thereon; and
(ii) a stator disposed about said rotor between and contacting said tapered ferrules, said stator including a piezoelectric cylinder wired and poled to function as an actuator and at least two electrodes contacting and separately disposed about said piezoelectric cylinder, said piezoelectric cylinder electrically coupled to a driver circuit tuned to the mechanical resonance frequency of said piezoelectric cylinder so as to vibrate said stator; and
(b) a cutting element extending from one end of said rotor, said rotor communicates vibrations from said stator to said cutting element.

9. The micro-disruptor of claim 8, further comprising a support cylinder disposed about and contacting said stator.

10. The micro-disruptor of claim 9, wherein said electrodes are disposed in a paired arrangement about said piezoelectric cylinder.

11. The micro-disruptor of claim 9, wherein said cutting element is a drill bit, a screw-shaped snare, or at least one blade.

12. The micro-disruptor of claim 9, further comprising:
(c) a guide wire attached to said micro-motor opposite said cutting element.

13. The micro-disruptor of claim 8, further comprising a third ferrule attached to said rotor between said cutting element and one said ferrule adjacent to said cutting element, said ferrule adjacent to said cutting element movable along said rotor and pressed against said stator by a spring.

14. A method for disrupting a blockage comprising the steps of:
(a) rotating a cutting element attached to a piezoelectric micro-motor disposed at one end of a guide wire;
(b) vibrating said piezoelectric micro-motor via a driver circuit;
(c) penetrating said blockage with said cutting element; and
(d) communicating vibrations from said piezoelectric micro-motor to said cutting element and into said blockage while penetrating said blockage.
